(19) United States
(12) Patent Application Publication
(10) Pub. No.: US 2012/0188715 A1
(43) Pub. Date: Jul. 26, 2012

(54) ENCLOSURE OF ELECTRONIC DEVICE

(75) Inventors: XIANG-KUN ZENG, Wuhan City (CN); ZHI-JIANG YAO, Wuhan City (CN); LI-FU XU, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/323,903

(22) Filed: Dec. 13, 2011

(30) Foreign Application Priority Data
Jan. 24, 2011 (CN) 201110025408.0

(51) Int. Cl. H05K 7/20

(52) U.S. Cl. 361/692; 361/690

(57) ABSTRACT

An enclosure of an electronic device includes a front panel including a plurality of first air guiding boards and a plurality of second air guiding boards. The plurality of first air guiding boards arrange a first air guiding layer, and the plurality of second air guiding boards arrange a second air guiding layer. A first gap is defined between adjacent two of the plurality of first air guiding boards, a second gap is defined between adjacent two of the plurality of second air guiding boards, and a third gap is defined between the first air guiding layer and the second air guiding layer. Each second air guiding board is located opposite to the first gap. An absorbing layer is placed on a side surface of each second air guiding board towards the first gap. The first gap communicates with the second gap and the third gap.

### BACKGROUND

1. Technical Field

The present disclosure relates to an enclosure of electronic device.

2. Description of Related Art

Enclosures of electronic devices, such as a chassis of a computer and a server, usually define a plurality of air vents. Air flows into and out of the electronic device through the plurality of the air vents, to cool the electronic components located in the electronic device. However, it is easy for dust to enter into the electronic device through the plurality of air vents and accumulate in the electronic device. Therefore, an improved enclosure of electronic devices may be desired.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an assembled, cutaway view of one embodiment of an enclosure of electronic device.

FIG. 2 is an isometric view of a front panel of the enclosure of electronic device of FIG. 1.

FIG. 3 is a cross-sectional view taken along the line III-III in FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

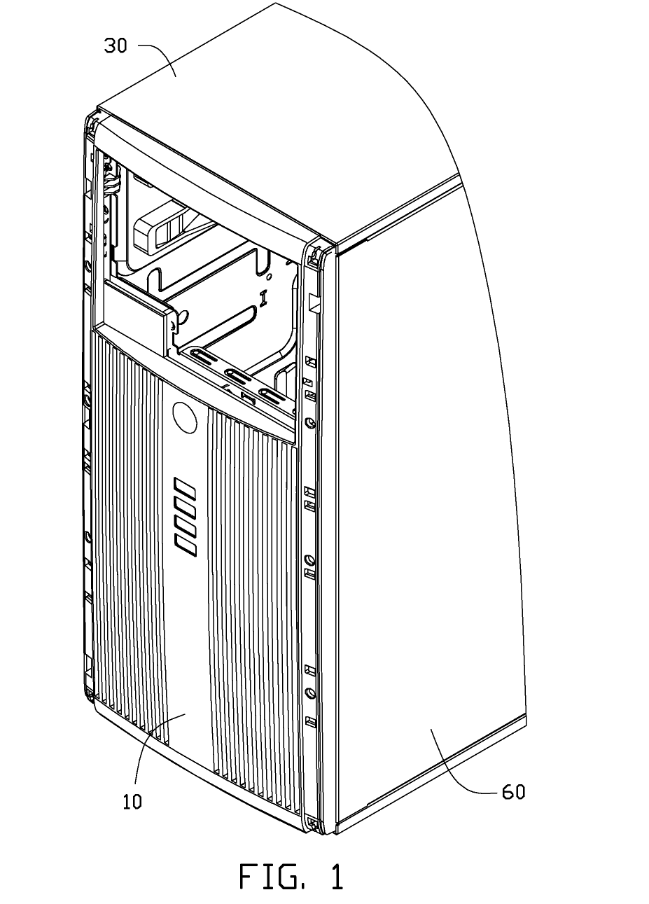

Referring to FIG. 1, an enclosure of an electronic device in one embodiment comprises a front panel 10, a rear panel (not shown) opposite to the front panel 10, a top panel 30, a bottom panel (not shown) opposite to the top panel 30, and two opposite side panels 60. In one embodiment, the electronic device may be a personal computer, a server computer, for example.

The front panel 10, the rear panel, the top panel 30, the bottom panel, and the two side panels together define a receiving space, the receiving space is adapted to receive a motherboard, a hard disk drive, for example.

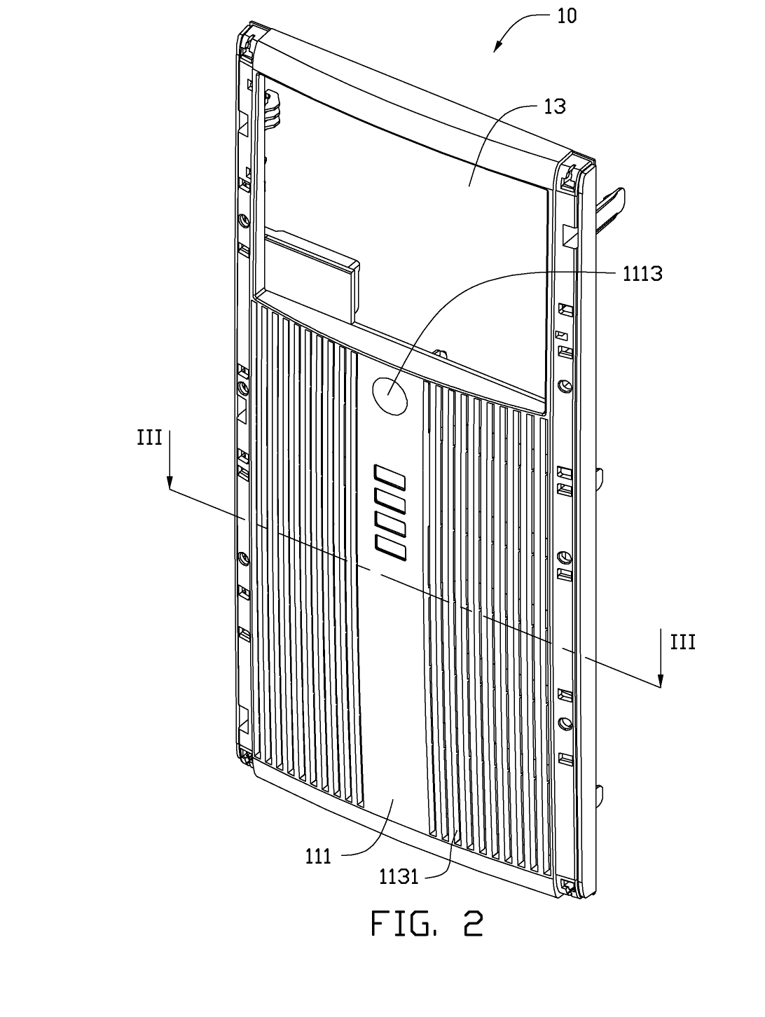

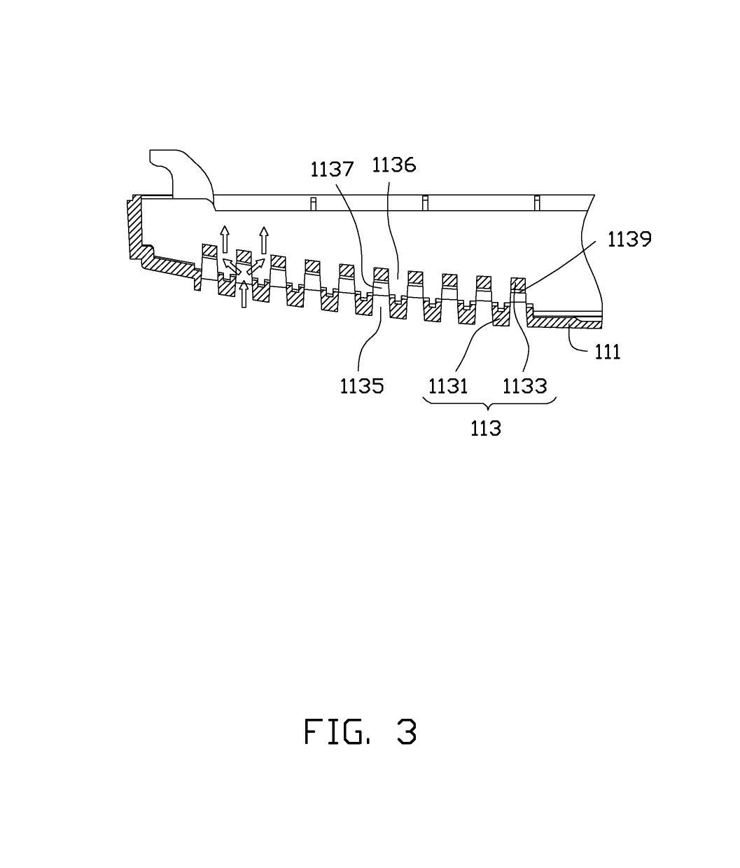

Referring to FIGS. 2 and 3, the front panel 10 defines an opening 13 and comprises an installation portion 111 and a plurality of ventilation portions 113. The opening 13 is for an optical disk driver (ODD) to pass through and is located above the installation portion 111 and the plurality of ventilation portions 113. The installation portion 111 defines a plurality of installation holes 1113 for installing a power switch and USB jacks. The installation portion 111 is located between adjacent two of the plurality of ventilation portions 113.

Each of the plurality of ventilation portions 113 comprises a first air guiding board 1131 and a second air guiding board 1133. The first air guiding board 1131 comprises a side surface facing the second air guiding board 1133. In one embodiment, the side surface of the first air guiding board 1131 is curved. Adjacent two of the first air guiding boards 1131 define a first gap 1135. A structure of the second air guiding board 1133 is similar to that of the first air guiding board 1131. Adjacent two of the second air guiding boards 1133 define a second gap 1136. The first air guiding board 1131 is opposite to the second gap 1136, and the width of the first air guiding board 1131 is substantially equal to that of the second gap 1136. The second air guiding board 1133 is opposite to the first gap 1135, and the width of the second air guiding board 1133 is substantially equal to that of the first gap 1135. A plurality of the first air guiding boards 1131 arrange a first air guiding layer. A plurality of the second air guiding boards 1133 arrange a second air guiding layer. A third gap 1137 is defined between the first air guiding layer and the second air guiding layer. The third gap 1137 communicates with the first gap 1135 and the second gap 1136. An adsorbing layer 1139, which can adsorb dust in the air, is adhered to a side surface of the second air guiding board 1133 towards the first gap 1135. An air path is defined by the first gap 1135, the third gap 1137 and the second gap 1136. In one embodiment, the material of the adsorbing layer 1139 is fiber, and the adsorbing layer 1139 is adhered to the side surface of the second air guiding board 1133.

Referring to FIG. 3, in use, air flows into the first gap 1135 and is blocked by the second air guiding board 1133, the adsorbing layer 1139 adsorbs the dust in the air. Then, the dust free air flows into the enclosure of the electronic device via the third gap 1137 and the second gap 1136.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. An enclosure of an electronic device, comprising:
a front panel comprising a plurality of first air guiding boards and a plurality of second air guiding boards; the plurality of first air guiding boards arranging a first air guiding layer, and the plurality of second air guiding boards arranging a second air guiding layer; a first gap defined between adjacent two of the plurality of first air guiding boards, a second gap defined between adjacent two of the plurality of second air guiding boards, and a third gap defined between the first air guiding layer and the second air guiding layer; each of the plurality of second air guiding boards located opposite to the first gap; an absorbing layer placed on a side surface of each of the plurality of second air guiding boards towards the first gap; and the first gap communicating with the second gap and the third gap.

2. The enclosure of claim 1, wherein a width of each of the plurality of first air guiding boards is substantially equal to a width of the second gap.

3. The enclosure of claim 1, wherein each of the plurality of first air guiding boards is opposite to the second gap, and the plurality of second air guiding boards is similar to the plurality of first air guiding boards.

4. The enclosure of claim 1, wherein the side surface of each of the plurality of second air guiding boards is curved.

5. The enclosure of claim 1, wherein the adsorbing layer is made of fiber.

6. The enclosure of claim 1, wherein the front panel further comprises an installing portion and a plurality of ventilation portions, each of the plurality of ventilation portions comprises one of the plurality of first air guiding boards and one of the plurality of second air guiding boards, and the installing portion is located between adjacent two of the plurality of ventilation portions.

7. An enclosure of an electronic device, comprising:
a front panel comprising a plurality of first air guiding boards and a plurality of second air guiding boards; the plurality of first air guiding boards arranging a first air guiding layer, and the plurality of second air guiding boards arranging a second air guiding layer; a first gap defined between adjacent two of the plurality of first air guiding boards, a second gap defined between adjacent two of the plurality of second air guiding boards, and a third gap defined between the first air guiding layer and the second air guiding layer; each of the plurality of second air guiding boards located opposite to the first gap, and each of the plurality of first air guiding boards located opposite to the second gap; an absorbing layer placed on a side surface of each of the plurality of second air guiding boards towards the first gap; and an air path is defined by the first gap, the third gap and the second gap.

8. The enclosure of claim 7, wherein a width of each of the plurality of first air guiding boards is substantially equal to a width of the second gap.

9. The enclosure of claim 7, wherein the plurality of second air guiding boards is similar to the plurality of first air guiding boards.

10. The enclosure of claim 7, wherein the side surface of each of the plurality of second air guiding boards is curved.

11. The enclosure of claim 7, wherein the adsorbing layer is made of fiber.

12. The enclosure of claim 7, wherein the front panel further comprises an installing portion and a plurality of ventilation portions, each of the plurality of ventilation portions comprises one of the plurality of first air guiding boards and one of the plurality of second air guiding boards, and the installing portion is located between adjacent two of the plurality of ventilation portions.
